(19) United States
(12) Patent Application Publication
(10) Pub. No.: US 2026/0011694 A1
(43) Pub. Date: Jan. 8, 2026

(54) Power Electronic Assemblies

(71) Applicant: Toyota Motor Engineering & Manufacturing North America, Inc., Plano, TX (US)

(72) Inventors: Feng Zhou, Ann Arbor, MI (US); Tianzhu Fan, Houston, TX (US); Shailesh Joshi, Ann Arbor, MI (US); Danny Lohan, West Bloomfield, MI (US)

(73) Assignee: Toyota Motor Engineering & Manufacturing North America, Inc., Plano, TX (US)

(21) Appl. No.: 18/765,814

(22) Filed: Jul. 8, 2024

(51) Int. Cl. H01L 25/07; H01L 23/367; H01L 23/48; H01L 23/50

(52) U.S. Cl. CPC H01L 25/072; H01L 23/3677; H01L 23/481; H01L 23/50

(57) ABSTRACT

A power electronics assembly includes a printed circuit board including a plurality of substrate layers. The plurality of substrate layers include a first core layer and a second core layer stacked vertically below the first core layer, wherein the first core layer comprises a first electrical component embedded therein and the second core layer comprises a second electrical component embedded therein. The first electrical component and the second electrical component are arranged in a vertical column.

### TECHNICAL FIELD

The present specification generally relates to power electronic assemblies and, more specifically, apparatus and methods for power electronic assemblies having a compact package size.

### BACKGROUND

Due to the increased use of electronics in vehicles, there is a need to make electronic systems more compact. One component of these electronic systems is a power electrical component used as a switch in an inverter or converter. Power electrical components have large cooling requirements due to the heat generated.

Additionally, there has been a trend for power electrical components conventionally composed of silicon to now be composed of silicon-carbide, gallium nitride, or gallium oxide. The use of silicon-carbide, gallium nitride, or gallium oxide causes a larger heat flux due to it defining a smaller device footprint. For these reasons, and more, there is a need to improve the cooling of power electrical components while maintaining a compact package size.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1 schematically depicts a power electronic assembly, according to one or more embodiments shown and described herein;

FIG. 2A schematically depicts a subassembly of the electrical component and the mounting substrate of the power electronic assembly of FIG. 1, according to one or more embodiments shown and described herein

FIG. 2B schematically depicts the mounting substrate of the subassembly of FIG. 2A, according to one or more embodiments shown and described herein;

FIG. 3 schematically depicts another power electronic assembly, according to one or more embodiments shown and described herein;

FIG. 4 schematically depicts yet another power electronic assembly, according to one or more embodiments shown and described herein;

FIG. 5 schematically depicts yet another power electronic assembly, according to one or more embodiments shown and described herein;

FIG. 6 schematically depicts yet another power electronic assembly, according to one or more embodiments shown and described herein; and

FIG. 7 schematically depicts yet another power electronic assembly, according to one or more embodiments shown and described herein.

### SUMMARY

In one embodiment, a power electronics assembly includes a printed circuit board including a plurality of substrate layers. The plurality of substrate layers include a first core layer and a second core layer stacked vertically below the first core layer, wherein the first core layer comprises a first electrical component embedded therein and the second core layer comprises a second electrical component embedded therein. The first electrical component and the second electrical component are arranged in a vertical column.

In another embodiment, a power electronic assembly includes a printed circuit board including a plurality of substrate layers and at least one mounted electronic. The plurality of substrate layers include a first core layer, a second core layer, and a first signal layer. The first core layer includes a first electrical component embedded therein. The second core layer is stacked vertically below the first core layer and includes a second electrical component embedded therein. The first electrical component and the second electrical component are arranged in a vertical column. The first signal layer is stacked vertically above the first core layer. The at least one mounted electronic is mounted to a top surface of the printed circuit board and electrically coupled to the first signal layer.

In yet another embodiment, a power electronic assembly includes a printed circuit board including a plurality of substrate layers. The plurality of substrate layers include a first core layer, a second core layer, a first signal layer, and a second signal layer. The first core layer includes a first electrical component embedded therein. The second core layer is stacked vertically below the first core layer and includes a second electrical component embedded therein. The first electrical component and the second electrical component are arranged in a vertical column. The first signal layer is stacked vertically above the first core layer. The second signal layer disposed between the first core layer and the second core layer.

These and additional features provided by the embodiments described herein will be more fully understood in view of the following detailed description, in conjunction with the drawings.

### DETAILED DESCRIPTION

Embodiments described herein are generally directed to power electronic assemblies having one or more vertical columns of electrical components embedded directly into a circuit board, such as a printed circuit board. By fully embedding the electrical components and arranging the electrical components in stacked columns, the power density of the assembly may increase while enabling sufficient heat dissipation from the electrical components.

The arrangements of the electrical components, the circuit board assemblies, and the power electronic assemblies described herein may be used in electrified vehicles, such as and without being limited to, an electric vehicle, a hybrid electric vehicle, any electric motor, generators, industrial tools, household appliances, and the like. The power electronic assemblies described herein may be electrically coupled to an electric motor and/or a battery and be configured as a converter or inverter circuit.

As used herein, an “electrical component” means any electrical component that generates waste heat, such as electrical components used to convert DC electrical power to AC electrical power and vice-versa. Non-limiting examples of electrical components include power metal-oxide-semiconductor field effect transistors (MOSFET), insulated-gate bipolar transistors (IGBT), thyristors, and power transistors.

As used herein, the phrase “fully embedded” means that each surface of a component is surrounded by a substrate. For example, when a power electronics device assembly is fully embedded by a circuit board substrate, it means that the material of the circuit board substrate covers each surface of the circuit board substrate. A component is “partially embedded” when one or more surfaces of the component are exposed.

As used herein, the terms “first,” “second,” and “third” may be used interchangeably to distinguish one component from another and are not intended to signify location or importance of the individual components.

As used herein, the term “vertically” is used directionally to refer to the direction in which the substrate layers of a power electronic assembly are stacked and is generally represented by the Z direction of the depicted coordinate systems. The term “vertically” is not intended to reference an absolute vertical direction or a vertical direction with respect to a larger assembly in which the power electronic assembly may be included.

As used herein, the singular forms “a,” “an,” and “the” include plural referents unless the context clearly dictates otherwise. Thus, for example, reference to “a” component includes aspects having two or more such components, unless the context clearly indicates otherwise.

Approximating language, as used herein throughout the specification and claims, is applied to modify any quantitative representation that could permissibly vary without resulting in a change in the basic function to which it is related. Accordingly, a value modified by a term or terms, such as “about,” “approximately,” and “substantially,” are not to be limited to the precise value specified. In at least some instances, the approximating language may correspond to the precision of an instrument for measuring the value, or the precision of the methods or machines for constructing or manufacturing the components and/or systems. In at least some instances, the approximating language may correspond to the precision of an instrument for measuring the value, or the precision of the methods or machines for constructing or manufacturing the components and/or systems. For example, the approximating language may refer to being within a 1, 2, 4, 5, 10, 15, or 20 percent margin in either individual values, range(s) of values and/or endpoints defining range(s) of values.

Various embodiments of power electronics device assemblies, circuit board assemblies, and power electronics assemblies are described in detail below. Whenever possible, the same reference numerals will be used throughout the drawings to refer to the same or like parts.

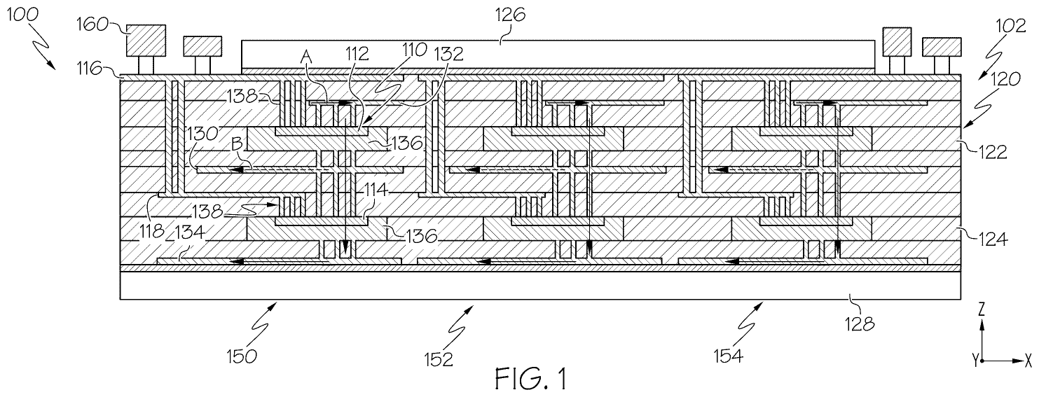

Referring to FIG. 1, an example power electronic assembly 100 is schematically depicted. The power electronic assembly 100 may include a printed circuit board 102 comprising a plurality of substrate layers 120 stacked in a vertical direction (e.g. in the Z-axis direction of the depicted coordinate system). The plurality of substrate layers 120 may be made from a dielectric material, such as FR-4, for example. As depicted, the power electronic assembly 100 may include eight individual substrate layers 120. However, a greater or fewer number of substrate layers 120 is contemplated and possible.

Embedded within the plurality of substrate layers 120 are a plurality of electrical components 110 that generate excess heat during operation that should be removed. The electrical components 110 may be power chips, such as insulated-gate bipolar transistors (“IGBT”), power diodes, IGBT/diode combinations, metal-oxide-semiconductor field-effect transistors (“MOSFET”) or other power semiconductor devices. The electrical components 110 may be fully embedded within the substrate layers such that the electrical components 110 are surrounded on all sides by the substrate layers 120. As depicted, each of the electrical components 110 may be mounted on an electrically conductive mounting substrate 136 within the substrate layers 120. In some embodiments, the electrical components 110 may be mounted generally on the top of and within a recess of mounting substrate 136. As depicted, in some embodiments, the power electronic assembly 100 may have six electrical components 110 that define a converter or inverter circuit, such as an inverter circuit of an electrified vehicle; however, other quantities of electrical components 110 are contemplated and possible.

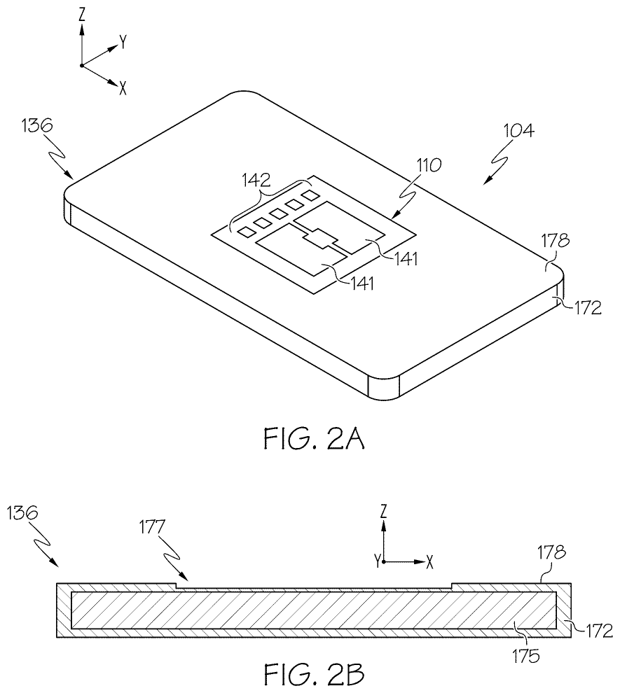

FIGS. 2A and 2B illustrate an example subassembly 104 of the electrical component 110 and the mounting substrate 136 in a top perspective view and a cross-sectional view, respectively. The subassembly 104 illustrated by FIGS. 2A and 2B includes an internal graphite layer 175 that is encapsulated by a metal layer 172. Together, the internal graphite layer 175 and metal layer 172 may make up the mounting substrate 136. The metal layer 172 includes a surface 178 having a recess 177 with dimensions to receive the electrical component 110. As described in more detail below, the metal layer 172 provides an electrically conductive surface 178 to which electrically conductive vias may contact to make an electrical connection to electrodes on a bottom surface of the electrical component 110. The example electrical component 110 is illustrated as having top electrodes 141 for passing switched current as well as a plurality of signal electrodes 142 for controlling the electrical component. The recess 177 may be formed by chemical etching, for example. The metal layers 172 may be made of any suitable metal or alloy. Copper and aluminum may be used as the metal layer 172 as non-limiting examples. Additional features of the subassembly 104 are described in U.S. patent application Ser. No. 17/874,462, titled Power Electronics Assemblies Having Embedded Power Electronics Devices and filed on Jul. 27, 2022, herein incorporated by reference. It should be understood that the mounting substrate 136 may take on other configurations.

Referring back to FIG. 1, in some embodiments, the substrate layers 120 may include a first core layer 122 in which a first electrical component 112 is embedded and a second core layer 124 in which a second electrical component 114 is embedded. The first core layer 122 may be stacked vertically above the second core layer 124, and the first electrical component 112 and the second electrical component 114 may be aligned such that the first electrical component 112 and the second electrical component 114 form a first vertical column 150 along the Z-axis. In some embodiments, the plurality of electrical components 110 may be arranged to form multiple vertical columns. For example, as depicted the power electronic assembly 100 may include six electrical components 110 arranged in the first vertical column 150, a second vertical column 152, and a third vertical column 154. In other embodiments, the power electronic assembly 100 may include a larger or smaller quantity of electrical components 110 which may be arranged in a larger or smaller quantity of columns.

Still referring to FIG. 1, disposed between the first core layer 122 and the second core layer 124 may be a first power layer 130. The first power layer 130 is an output layer comprising conductive material, such as copper, which may be electrically coupled to an output terminal that is further electrically coupled to a load, such as an electric motor, or a battery. Accordingly, a first electrical component 112 and the second electrical component 114 may be in electrical communication with the first power layer 130 such that the first electrical component 112 and the second electrical component 114 supply an output to the output terminal.

The power electronic assembly 100 includes a second power layer 132 which may be a positive layer comprising conductive material, such as copper, which may electrically couple the second power layer 132 to a positive terminal of a source, such as a battery. As depicted, in some embodiments, the second power layer 132 may be arranged vertically above the first core layer 122 and the second core layer 124. The power electronic assembly 100 includes a third power layer 134 which may be a negative layer comprising conductive material, such copper, which may electrically couple the third power layer 134 to a negative terminal of a source, such as a battery. As depicted, in some embodiments, the third power layer 134 may be arranged vertically below the first core layer 122 and the second core layer 124. Disposed between the core layers 122, 124 and the power layers 130, 132, 134 may be a plurality of conductive vias 138 extending in the vertical direction (e.g. the Z-axis direction of the depicted coordinate system), which may electrically couple each of the core layers 122, 124 to each of the power layers 130, 132, 134. In this way, electrical current may travel through the core layers and to the electrical components 110. In particular, an electrical current may originate at a positive terminal, travel through the second power layer 132, through the first electrical component 112, through the second electrical component 114, and through the third power layer 134 to a negative terminal as shown by the depicted arrows A and B, where arrow A indicates the input current flow, arrow B indicates the output generated by the electrical components 110.

The power electronic assembly 100 may include a plurality of signal layers configured to transmit an electric signal such as a first signal layer 116 and a second signal layer 118 to control the electrical components 110 (i.e., switch them on and off). The first signal layer 116 and the second signal layer 118 may be separated by one or more core layers and/or power layers which may prevent cross-talk between the first signal layer 116 and the second signal layer 118. As depicted, in some embodiments, the first signal layer 116 may be disposed vertically above the first core layer 122. The second signal layer 118 may be disposed between the first core layer 122 and the second core layer 124.

The second signal layer 118 may be electrically coupled to the first signal layer 116 via the conductive vias 138. In this way, the second signal layer 118 may receive a signal from one or more mounted electronics 160 mounted on the first signal layer 116, as described in greater detail herein. The first signal layer 116 may be electrically coupled to the first core layer 122, and the second signal layer 118 may be electrically coupled to the second core layer 124 by the conductive vias 138. In this way, the first electrical component 112 and the second electrical component 114 may be in communication with the one or more mounted electronics 140 via the first signal layer 116 and the second signal layer 118, respectively.

The power electronic assembly 100 may include one or more mounted electronics 160. The one or more mounted electronics 160 may include resistors, capacitors, inductors, gate drive components, or other components. In embodiments, the one or more mounted electronics 160 may be mounted to a top surface of the printed circuit board 102. The one or more mounted electronics 160 may be electrically coupled to the first signal layer 116. In this way, the one or more mounted electronics 160 may be in communication with the electrical components (e.g., the first electrical component 112 and the second electrical component 114 of the pair of electrical components in the vertical column 150) via the first signal layer 116, the second signal layer 118, and the conductive vias.

Although the power layers 130, 132, 134 and the signal layers 116, 118 are described primarily in relation to the first electrical component 112 and the second electrical component 114 of the first vertical column 150, it should be understood that the descriptions apply equally to the electrical components of the second vertical column 152 and the third vertical column 154. In other words, the first electrical component 112 and the second electrical component 114 of each of the vertical columns 150, 152, 154 may receive an input via the second power layer 132 and may supply an output via the first power layer 130. Similarly, the first electrical component of each of the vertical columns 150, 152, 154 may communicate with the one or more mounted electronics 160 via the first signal layer 116. As depicted, the first vertical column 150, the second vertical column 152 and the third vertical column 154 may be similar. However, the first vertical column 150, the second vertical column 152 and the third vertical column 154 need not be the same. In some embodiments, there may be variation between the first vertical column 150, the second vertical column 152 and the third vertical column 154.

Still referring to FIG. 1, the power electronic assembly 100 may include a first cooling plate 126 and a second cooling plate 128. The first cooling plate 126 and the second cooling plate 128 may each be comprised of a thermally conductive material such that the first cooling plate 126 and the second cooling plate 128 are configured to pull heat away from the printed circuit board 102. In this way, the first cooling plate 126 and the second cooling plate 128 may decrease the temperature of the printed circuit board 102 via conduction and convection. In some embodiments, the first cooling plate 126 and the second cooling plate 128 may be made from copper, aluminum, graphite, composite materials, or other thermally conductive material.

As depicted, in embodiments, the first cooling plate 126 may be arranged on a first side of the printed circuit board 102. The second cooling plate 128 may be arranged one a second side of the printed circuit board 102 opposite the first side. In this way, heat generated by the electrical components 110 may be drawn from the printed circuit board 102 in two direction (i.e., the +Z-axis direction and the −Z-axis direction of the depicted coordinate system). In some embodiments, the first cooling plate 126 may directly abut the first signal layer 116, and the second cooling plate 128 may directly abut the third power layer 134, as depicted.

In some embodiments, in addition or in alternative to the first cooling plate 126 and the second cooling plate 128, the power electronic assembly 100 may include one or more convective cooling elements, such as fans or liquid impingement cooling flows. In some embodiments, the printed circuit board 102 may be submersed within a cooler or submerged in a cooling fluid.

In light of FIG. 1, it will be appreciated that arrangement of the electrical components 110 within the printed circuit board 102 may increase the power density of the power electronic assembly 100. Specifically, by fully embedding the electrical components 110 within the substrate layers 120 and by stacking the electrical components 110 such that the electrical components 110 are positioned in vertical columns, the power density may be increased. In particular, the arrangement of the power electronic assembly 100 may enable both decrease in size of the printed circuit board 102 and a decrease in inductance. The first cooling plate 126 and the second cooling plate 128 may be arranged on a first and a second side of the printed circuit board 102, respectively, and may dissipate heat from the printed circuit board 102 and prevent overheating of the printed circuit board 102 due to the increased power density.

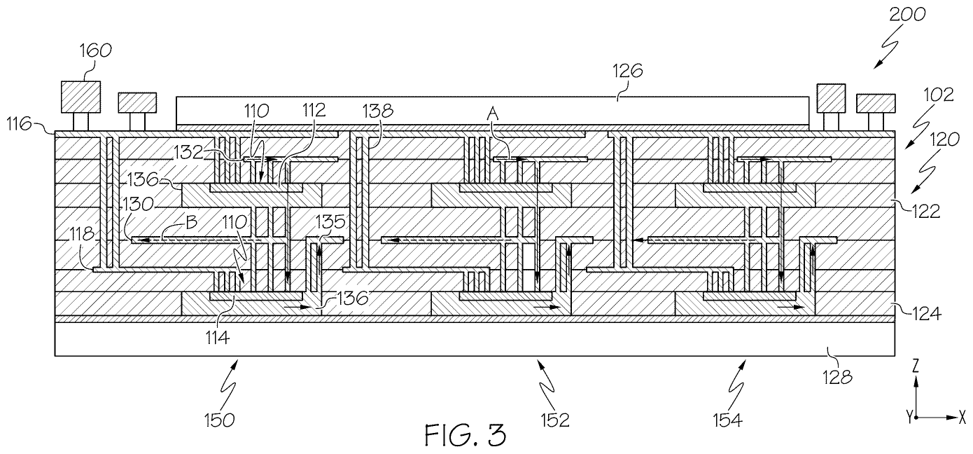

Referring now to FIG. 3, an embodiment of a power electronic assembly 200 is schematically depicted. The power electronic assembly 200 is similar to the power electronic assembly 100. Accordingly, like numbers will be used to refer to like features. For example, the power electronic assembly 200 may include a first electrical component 112 and a second electrical component 114 arranged in a first vertical column 150.

The power electronic assembly 200 may include a first power layer 130 disposed between the first core layer 122 and the second core layer 124. The first power layer 130 may be configured as the output layer that is coupled to an output terminal that is further electrically coupled to a load, such as an electric motor. The first electrical component 112 and the second electrical component 114 of the first vertical column 150 may be in electrical communication with the first power layer 130 such that the first electrical component 112 and the second electrical component 114 supply an output. Portions 135 of the first power layer 130 may additionally be configured as a negative layer connecting the first electrical component 112 and the second electrical component 114 to a negative terminal. In other words, the first power layer 130 may comprise conductive material connecting the first electrical component 112 and the second electrical component 114 to the output terminal and separate conductive material connecting the first electrical component 112 and the second electrical component 114 to the negative terminal. It is noted that the portions 135 of the first power layer 130 couple to the negative terminal extend along the Y-axis. Accordingly, the power electronic assembly 200 may have fewer substrate layers 120 as compared to embodiments having distinct power layers for electrical connection to the ground terminal and to the negative terminal.

The power electronic assembly 200 may include a second power layer 132 that is substantially similar to the second power layer 132 described with reference to FIG. 1, hereinabove. Specifically, the power electronic assembly 200 may have a second power layer 132 disposed vertically above the first core layer 122 and electrically coupled to a positive terminal. Accordingly, an electrical current may travel from the positive terminal, through the second power layer 132, through the first core layer 122, through the second core layer 124, and through the first power layer 130 to the negative terminal.

As depicted, the second core layer 124 may be a lower most layer of the power electronic assembly 200, and the first core layer 122 may be stacked vertically above the second core layer 124. Accordingly, in some embodiments, the second core layer may directly abut the second cooling plate 128.

Although the power layers 130, 132 and the core layers 122, 124 are described primarily in relation to the first electrical component 112 and the second electrical component 114 of the first vertical column 150, it should be understood that the descriptions apply equally to the electrical components of the second vertical column 152 and the third vertical column 154 as depicted in FIG. 2.

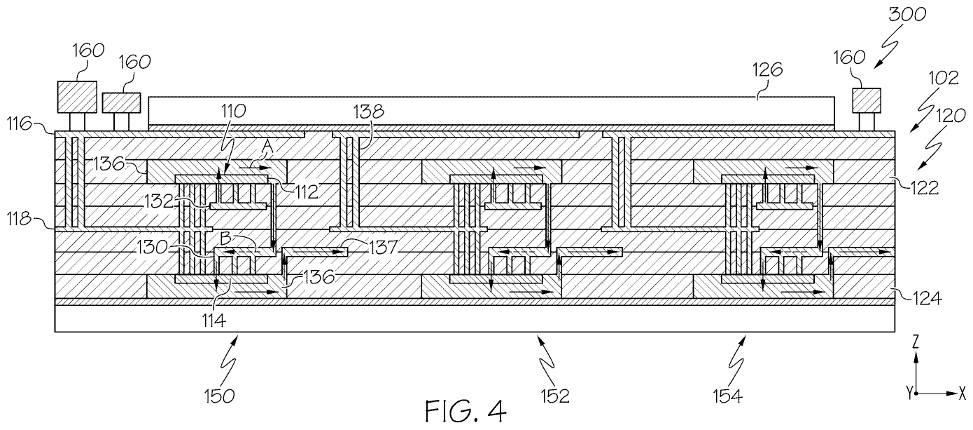

Referring now to FIG. 4, an embodiment of a power electronic assembly 300 is schematically depicted. The power electronic assembly 300 is similar to the power electronic assemblies 100 and 200. Accordingly, like numbers are used to refer to like features. For example, the power electronic assembly 300 may include a first electrical component 112 and a second electrical component 114 arranged in a first vertical column 150. Like the power electronic assembly 200, the power electronic assembly 300 may include a first power layer 130 electrically connecting the first electrical component 112 and the second electrical component 114 to both an output terminal and a negative terminal (e.g., by portions 137 extending along the Y-axis as indicated by arrows A). However, the arrangement of the substrate layers 120, including the first power layer 130, may differ. Additionally, the first electrical component 112 and the second electrical component 114 may be arranged facing each other.

The first electrical component 112 may be embedded within the first core layer 122 such that the first electrical component 112 is assembled at the bottom of the first core layer 122. In other words, the first electrical component 112 may be positioned generally below the mounting substrate 136. Comparatively, the second electrical component 114 may be assembled at the top of the second core layer 124 such that the second electronic assembly is positioned generally below the mounting substrate 136. In this way, the first electrical component 112 and the second electrical component 114 can be described as facing each other or arranged in a mirrored configuration.

Still referring to FIG. 4, the second signal layer 118 may be positioned between the first core layer 122 and the second core layer 124 and may be electrically coupled to both the first electrical component 112 and the second electrical component 114 with the conductive vias 138. The first signal layer 116, positioned at the top of the plurality of substrate layers 120, may be electrically coupled to the second signal layer 118 with the conductive vias 138. In this way, the first signal layer 116 and the second signal layer 118 may enable communication between the mounted electrical components and the first electrical component 112 and the second electrical component 114.

The first power layer 130 may be disposed between the first core layer 122 and the second core layer 124. The power electronic assembly 300 may have a second power layer 132 disposed between the first core layer 122 and the second core layer 124 that may be electrically connected to a positive terminal. Disposed between the first power layer 130 and the second power layer 132 may be the second signal layer 118. This arrangement of the first power layer 130, the second power layer 132, and the second signal layer 118 enables the second signal layer 118 to separate the first power layer 130 and second power layer 132. This may preventing unintentional shorting of the circuit.

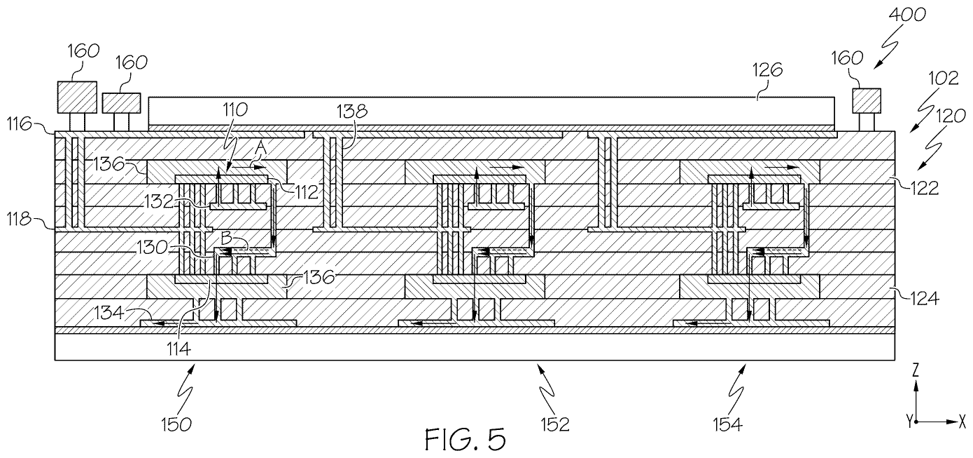

Referring now to FIG. 5, an embodiment of a power electronic assembly 400 is schematically depicted. The power electronic assembly 400 is similar to the power electronic assemblies 100, 200, and 300. Accordingly, like numbers are used to refer to like features. For example, the power electronic assembly 400 may include a first electrical component 112 and a second electrical component 114 arranged in a first vertical column 150. Similar to the power electronic assembly 300, the first electrical component 112 and the second electrical component 114 may be arranged facing each other. However, unlike the power electronic assembly 300, the first power layer 130 may electrically connect the first electrical component 112 and the second electrical component 114 to the output terminal while a third power layer 134 electrically connects the first electrical component 112 and the second electrical component 114 to the negative terminal. Accordingly, the specific arrangement of the substrate layers 120 may differ.

As depicted, the first electrical component 112 and the second electrical component 114 may be arranged facing each other, or in a mirrored configuration. The first signal layer 116 may be positioned at the top of plurality of substrate layers 120, and the second signal layer 118 may be positioned between the first core layer 122 and the second core layer 124, such as described with reference to the power electronic assembly 300, hereinabove.

Still referring to FIG. 5, the power electronic assembly 400 may have a first power layer 130 disposed between the first core layer 122 and the second core layer 124 that may electrically connect the first electrical component 112 and the second electrical component 114 to the output terminal. The power electronic assembly 400 may have a second power layer 132 disposed between the first core layer 122 and the second core layer 124 that may electrically connect the first electrical component 112 and the second electrical component 114 to a positive terminal. It is noted that the input current path as indicated by arrows A passes within the same plane as the output of the first power layer 130. The first power layer 130 includes conductive traces offset from the output connection along the Y-axis.

Disposed between the first power layer 130 and the second power layer 132 may be the second signal layer 118. The second signal layer 118 may therefore separate the first power layer 130 and second power layer 132, thereby preventing unintentional shorting of the circuit. Disposed beneath the second power layer 132 and adjacent the second cooling plate 128 may be the third power layer 134, which may electrically connect the first electrical component 112 and the second electrical component 114 to a negative terminal.

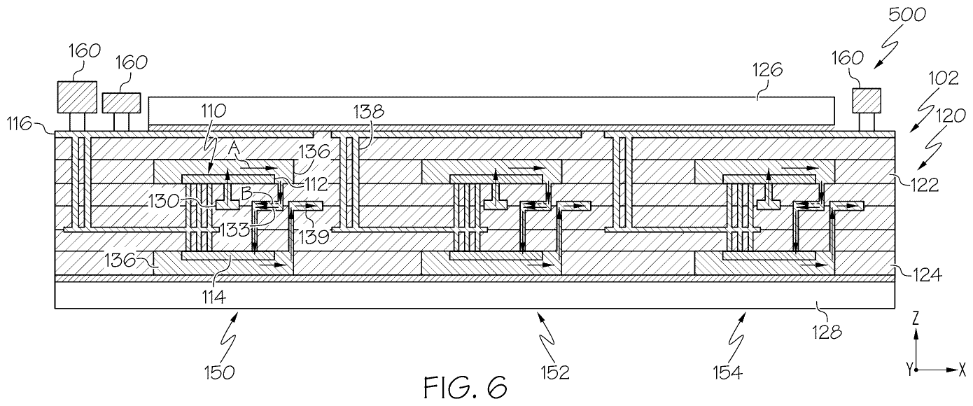

Referring now to FIG. 6, an embodiment of a power electronic assembly 500 is schematically depicted. The power electronic assembly 500 is similar to the power electronic assemblies 100, 200, 300, and 400. Accordingly, like numbers are used to refer to like features. For example, the power electronic assembly 500 may include a first electrical component 112 and a second electrical component 114 arranged in a first vertical column 150. Like the power electronic assemblies 300 and 400, the first electrical component 112 and the second electrical component 114 may be arranged facing each other. However, unlike the power electronic assemblies 100, 200, and 300, the power electronic assembly 400 include only a first power layer 130 and may not include a second power layer 132 or a third power layer 134 as described with reference to the earlier embodiments. Rather, the first power layer 130 has electrically conductive portions that are electrically coupled to a positive terminal, an output terminal, and a negative terminal.

As depicted, the first electrical component 112 and the second electrical component 114 may be arranged facing each other, or in a mirrored configuration. The first signal layer 116 may be positioned at the top of plurality of substrate layers 120, and the second signal layer 118 may be positioned between the first core layer 122 and the second core layer 124, such as described with reference to the power electronic assemblies 300 and 400, hereinabove.

The power electronic assembly 500 may include a first power layer 130 that may be coupled to a positive terminal, negative terminal (by electrically conductive portion 139), and output terminal (by electrically conductive portion 133). Accordingly, the power electronic assembly 500 may include a single power layer. The first power layer 130 may be disposed between the first core layer 122 and second core layer 124. The first power layer 130 may be electrically connected to the first core layer 122 and second core layer 124 by the conductive vias 138. Accordingly, an electrical current may travel from the positive terminal, through the first power layer 130, through the first core layer 122, back through the first power layer 130, through the second core layer 124, and back through the first power layer 130 to the negative terminal. By using a single power layer, the power electronic assembly 500 may include six substrate layers 120.

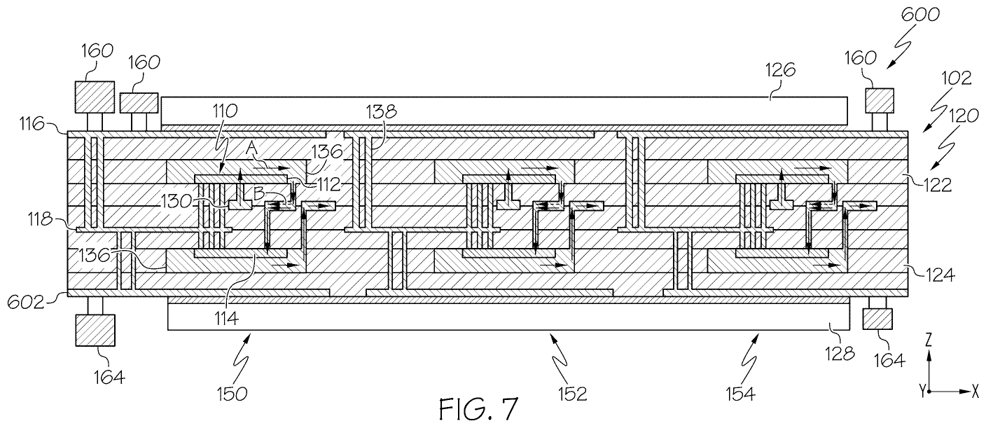

Referring now to FIG. 7, an embodiment of a power electronic assembly 600 is schematically depicted. The power electronic assembly 600 is similar to the power electronic assemblies 100, 200, 300, 400, and 500. Accordingly, like numbers are used to refer to like features. For example, the power electronic assembly 600 may include a first electrical component 112 and a second electrical component 114 arranged in a first vertical column 150. As will be described herein, the power electronic assembly 600 may include a second selection of one or more mounted electronics 144 in addition to the one or more mounted electronics 140.

The power electronic assembly 600 may include a first power layer 130, which may be a single power layer disposed between the first core layer 122 and second core layer 124, such as described with reference to the power electronic assembly 500 hereinabove.

The power electronic assembly 600 may a first signal layer 116 disposed vertically above the first core layer 122, a second signal layer 118 disposed between the first core layer 122 and the second core layer 124, and a third signal layer 602 disposed vertically below the second core layer 124. One or more mounted electronics 160 may be electrically coupled to the first signal layer 116. The second selection of one or more mounted electronics 164 may be electrically coupled to the third signal layer 602. The first signal layer 116 and the third signal layer 602 may each be electrically coupled to the second signal layer 118 by the conductive vias 138. The second signal layer 118 may be electrically connected to the first electrical component 112 and the second electrical component 114 by the conductive vias 138. In this way, both the first electrical component 112 and the second electrical component 114 may be in communication with the mounted electronics 160 and the second selection of one or more mounted electronics 164 via the second signal layer 118. This arrangement may increase the available area for mounted electronics by enabling mounting along both the top and bottom of the printed circuit board 102.

In view of the above, it should now be understood that at least some embodiments of the present disclosure are directed to a power electronics assembly that includes a printed circuit board including a plurality of substrate layers. The plurality of substrate layers include a first core layer and a second core layer stacked vertically below the first core layer, wherein the first core layer comprises a first electrical component embedded therein and the second core layer comprises a second electrical component embedded therein. The first electrical component and the second electrical component are arranged in a column.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

It will be apparent to those skilled in the art that various modifications and variations can be made to the embodiments described herein without departing from the scope of the claimed subject matter. Thus, it is intended that the specification cover the modifications and variations of the various embodiments described herein provided such modification and variations come within the scope of the appended claims and their equivalents.

What is claimed is:

1. A power electronic assembly comprising:
a printed circuit board comprising a plurality of substrate layers stacked in a vertical direction, the plurality of substrate layers comprising:
a first core layer comprising a first electrical component embedded therein; and
a second core layer stacked vertically below the first core layer, the second core layer comprising a second electrical component embedded therein, wherein the first electrical component and the second electrical component are arranged in a vertical column.

2. The power electronic assembly of claim 1, wherein the first electrical component and the second electrical component are each embedded within a conductive mounting substrate.

3. The power electronic assembly of claim 1, further comprising three columns of fully embedded electrical components.

4. The power electronic assembly of claim 1, further comprising a first cooling plate disposed on a first side of the printed circuit board and a second cooling plate disposed on a second side of the printed circuit board opposite the first side.

5. The power electronic assembly of claim 4, wherein the second core layer directly abuts the second cooling plate.

6. The power electronic assembly of claim 1, further comprising a signal layer disposed between the first core layer and the second core layer.

7. The power electronic assembly of claim 1, further comprising a power layer disposed between the first core layer and the second core layer.

8. The power electronic assembly of claim 1, further comprising a power layer disposed vertically above the first core layer.

9. The power electronic assembly of claim 1, further comprising a power layer disposed below the second core layer.

10. The power electronic assembly of claim 1, wherein the first electrical component and the second electrical component are arranged facing each other.

11. A power electronic assembly comprising:
a printed circuit board comprising a plurality of substrate layers, the plurality of substrate layers comprising:
a first core layer comprising a first electrical component embedded therein;
a second core layer stacked vertically below the first core layer, the second core layer comprising a second electrical component embedded therein, wherein the first electrical component and the second electrical component are arranged in a vertical column; and
a first signal layer stacked vertically above the first core layer; and
at least one mounted electronic mounted to a top surface of the printed circuit board and electrically coupled to the first signal layer.

12. The power electronic assembly of claim 11, wherein the printed circuit board comprises a second vertical column of embedded electrical components.

13. The power electronic assembly of claim 11, further comprising a second signal layer disposed between the first core layer and the second core layer.

14. The power electronic assembly of claim 11, further comprising a cooling plate abutting the first signal layer.

15. The power electronic assembly of claim 11, wherein the plurality of substrate layers comprises at least six individual substrate layers.

16. The power electronic assembly of claim 11, further comprising:
a second signal layer disposed below the second core layer; and
a second mounted electronic electrically coupled to the second signal layer.

17. A power electronic assembly comprising:
a printed circuit board comprising a plurality of substrate layers, the plurality of substrate layers comprising:
a first core layer comprising a first electrical component embedded therein;
a second core layer stacked vertically below the first core layer, the second core layer comprising a second electrical component embedded therein, wherein the first electrical component and the second electrical component are arranged in a vertical column;
a first signal layer disposed above the first core layer; and
a second signal layer disposed between the first core layer and the second core layer.

18. The power electronic assembly of claim 17, wherein the second signal layer is electrically coupled to the second electrical component.

19. The power electronic assembly of claim 17, wherein the second signal layer is electrically coupled to the first electrical component.

20. The power electronic assembly of claim 17, further comprising at least one mounted electronic coupled to the first signal layer.
